(19) United States
(12) Patent Application Publication
(10) Pub. No.: US 2026/0198180 A1
(43) Pub. Date: Jul. 9, 2026

(54) DISPLAY DEVICE, METHOD OF MANUFACTURING THE SAME, AND ELECTRONIC DEVICE INCLUDING THE DISPLAY DEVICE

(71) Applicant: Samsung Display Co., Ltd., Yongin-si (KR)

(72) Inventors: HYUNGGI JUNG, Yongin-si (KR); YOUNGSEOK PARK, Yongin-si (KR); SOON CHANG YEON, Yongin-si (KR)

(21) Appl. No.: 19/412,548

(22) Filed: Dec. 8, 2025

(30) Foreign Application Priority Data
Jan. 3, 2025 (KR) 10-2025-0000890

(51) Int. Cl. H10K 59/121; H10D 86/01; H10D 86/40; H10D 86/60; H10K 59/12; H10K 102/00

(52) U.S. Cl. CPC H10K 59/1213; H10D 86/0231; H10D 86/451; H10D 86/60; H10K 59/1201; H10K 2102/341; H10K 2102/351

(57) ABSTRACT

A display device includes a substrate, a thin-film transistor on the substrate, and a light-emitting diode electrically connected to the thin-film transistor. The thin-film transistor includes a semiconductor layer, a gate electrode, and an insulating layer between the semiconductor layer and the gate electrode. The insulating layer includes an overlapping portion overlapping the gate electrode and extension portions respectively positioned on outer sides of the overlapping portion, wherein a thickness of the overlapping portion is greater than that of each of the extension portions.

### CROSS-REFERENCE TO RELATED APPLICATION

The present application claims priority to and the benefit of Korean Patent Application No. 10-2025-0000890, filed on Jan. 3, 2025, in the Korean Intellectual Property Office, the entire disclosure of which is incorporated herein by reference.

### BACKGROUND

### 1. Field

Embodiments of the present disclosure relate to a display device, a method of manufacturing the same, and an electronic device including the display device.

### 2. Description of the Related Art

In recent years, various types (kinds) of lightweight and small-sized (compact) flat-panel display devices have been developed. Examples of flat-panel display devices include a liquid crystal display (LCD), a field emission display (FED), a plasma display panel (PDP), an organic light-emitting display (OLED), and/or the like.

Among the flat-panel display devices, OLEDs display images by using organic light-emitting diodes that emit light through the recombination of electrons and holes. Such OLEDs are emerging as next-generation displays due to their fast response speeds and concurrently (e.g., simultaneously) run on low power consumption.

The above information disclosed in this Background section is intended to enhance understanding of the background of the disclosure and may contain information that does not constitute prior art.

### SUMMARY

Aspects of one or more embodiments of the present disclosure are directed to a display device with improved stability and improved electrical characteristics and an electronic device including the display device.

For example, aspects of one or more embodiments of the present disclosure are directed to a display device including an insulating layer under a gate electrode that has an overlapping portion that overlaps the gate electrode and extension portions adjacent to and on side ends of the overlapping portion. The inclusion of the extension portions may reduce the likelihood of contamination alongside edges of the insulating layer under the gate electrode connecting the gate electrode to the semiconductive layer of the transistor, thus reducing the likelihood of a short circuit. Additional embodiments include an electronic device including the display device and a method of manufacturing in the display device.

Additional aspects will be set forth in part in the description which follows and, in part, will be apparent from the description, or may be learned by practice of the presented embodiments of the disclosure. In addition, it will also be appreciated that the problems to be solved by the present disclosure and advantages of the present disclosure can be realized by the embodiments and/or a (e.g., any suitable) combination thereof indicated in the claims of the patent.

One or more embodiments of the present disclosure provide a display device including: a substrate; a thin-film transistor on the substrate; and a light-emitting diode electrically connected to the thin-film transistor, wherein the thin-film transistor includes a semiconductor layer, a gate electrode, and an insulating layer between the semiconductor layer and the gate electrode, wherein the insulating layer includes an overlapping portion overlapping the gate electrode and extension portions respectively positioned on outer sides of the overlapping portion, wherein a thickness of the overlapping portion is greater than that of each of the extension portions.

In one or more embodiments, a width of each of the extension portions may be in a range of about 0.5 μm to about 1 μm.

In one or more embodiments, a ratio of a width of the overlapping portion to a width of each of the extension portions may be in a range of about 3 to about 4.

In one or more embodiments, the display device may further include a buffer layer between the substrate and the semiconductor layer.

In one or more embodiments, the semiconductor layer may include a source area, a drain area, and a channel area between the source area and the drain area, wherein the insulating layer may be positioned on the channel area.

In one or more embodiments, a thickness of the channel area may be greater than thicknesses of the source area and the drain area.

In one or more embodiments, a width of the overlapping portion may be in a range of about 2 μm to about 3 μm.

One or more embodiments of the present disclosure provide a method of manufacturing the display device, the method including: sequentially stacking a semiconductor layer, an insulating layer, a gate electrode, and a photoresist on a substrate; after patterning the photoresist, performing a first etching on the gate electrode so that the gate electrode has a first width; performing a first etching on the insulating layer by using the gate electrode as a mask; performing a second etching on the gate electrode by using the photoresist as a mask so that the gate electrode has a second width smaller than the first width; and after performing the second etching on the gate electrode, performing a second etching on the insulating layer by using the gate electrode as a mask to form an overlapping portion overlapping with the gate electrode and extension portions respectively positioned on outer sides of the overlapping portion, the extension portions each having a thickness smaller than that of the overlapping portion.

In one or more embodiments, the first etching on the insulating layer and the first etching on the gate electrode may be performed by dry etching.

In one or more embodiments, during the first etching on the insulating layer, a width of the photoresist may be reduced together with the insulating layer.

In one or more embodiments, the second etching on the insulating layer and the second etching on the gate electrode may be performed by dry etching.

In one or more embodiments, the semiconductor layer may include a source area, a drain area, and a channel area positioned between the source area and the drain area, and during the second etching on the gate electrode, the source area and the drain area may be formed thinner than the channel area.

In one or more embodiments, a ratio of a thickness of the channel area to thicknesses of each of the source area and the drain area may be in a range of about 1.1 to about 1.3.

In one or more embodiments, during the first etching on the insulating layer, a residual film of the insulating layer may be formed on the semiconductor layer.

In one or more embodiments, during the second etching on the insulating layer, a ratio of a thickness of the overlapping portion to a thickness of each of the extension portions may be in a range of about 1.2 to about 3.

In one or more embodiments, a width of each of the extension portions may be in a range of about 0.5 μm to about 1 μm.

In one or more embodiments, a ratio of a width of the overlapping portion to a width of each of the extension portions may be in a range of about 3 to about 4.

In one or more embodiments, the method may further include forming a buffer layer on the substrate.

In one or more embodiments, the method may further include, after the performing of the second etching on the insulating layer, stripping the photoresist.

One or more embodiments of the present disclosure provide an electronic device including: a memory configured to store at least one program; a processor operable by executing the at least one program; a display device configured to receive data from the processor to provide visual information; and a power module configured to supply power to the display device; wherein the display device includes: a substrate; a thin-film transistor on the substrate; and a light-emitting diode electrically connected to the thin-film transistor; wherein the thin-film transistor includes a semiconductor layer, a gate electrode, and an insulating layer between the semiconductor layer and the gate electrode, and the insulating layer includes an overlapping portion overlapping the gate electrode and extension portions respectively positioned on outer sides of the overlapping portion, and a thickness of the overlapping portion is greater than that of each of the extension portions.

In one or more embodiments, a width of each of the extension portions may be in a range of about 0.5 μm to about 1 μm.

In one or more embodiments, a ratio of a width of the overlapping portion to a width of each of the extension portions may be in a range of about 3 to about 4.

In one or more embodiments, a ratio of a thickness of the overlapping portion to a thickness of each of the extension portions may be in a range of about 1.2 to about 3.

### BRIEF DESCRIPTION OF THE DRAWINGS

The accompanying drawings are included to provide a further understanding of the present disclosure, and are incorporated in and constitute a part of this specification. The drawings illustrate example embodiments of the present disclosure and, together with the description, serve to explain principles of the present disclosure. In the drawings:

FIG. 1 is a plan view schematically illustrating a display device according to one or more embodiments of the present disclosure;

FIG. 2 is a perspective view schematically illustrating a bent shape of the display device of FIG. 1, according to one or more embodiments of the present disclosure;

FIG. 3 is a schematic block view illustrating a structure of the display device of FIG. 1, according to one or more embodiments of the present disclosure;

FIG. 4 is a circuit diagram illustrating an equivalent circuit of a single sub-pixel of the display device of FIG. 1, according to one or more embodiments of the present disclosure;

FIG. 5 is a schematic cross-sectional view taken along the line A-A′ of FIG. 1, according to one or more embodiments of the present disclosure;

FIGS. 6-10 are schematic cross-sectional views of a method of manufacturing a transistor of FIG. 5, according to one or more embodiments of the present disclosure;

FIG. 11 is a schematic cross-sectional view of a step (e.g., act or task) of a method of manufacturing a transistor of FIG. 5, according to one or more embodiments of the present disclosure;

FIG. 12 is a block diagram of an electronic device according to one or more embodiments of the present disclosure; and

FIG. 13 is a schematic view of electronic devices according to embodiments of the present disclosure.

### DETAILED DESCRIPTION

The present disclosure may be modified in many alternate forms, and thus specific embodiments will be illustrated in the drawings and described in more detail. It should be understood, however, that this is not intended to limit the present disclosure to the particular forms disclosed, but rather, is intended to cover all modifications, equivalents, and alternatives falling within the spirit and scope of the present disclosure.

Hereinafter, example embodiments will be described in more detail with reference to the accompanying drawings. The present disclosure, however, may be embodied in various different forms, and should not be construed as being limited to only the illustrated embodiments herein. Rather, these embodiments are provided as examples so that this disclosure will be thorough and complete, and will fully convey the aspects and features of the present disclosure to those skilled in the art. Accordingly, processes, elements, and techniques that are not necessary to those having ordinary skill in the art for a complete understanding of the aspects and features of the present disclosure may not be described.

It will be understood that, although the terms “first,” “second,” “third,” etc., may be used herein to describe various elements, components, regions, layers and/or sections, these elements, components, regions, layers and/or sections should not be limited by these terms. These terms are used to distinguish one element, component, region, layer or section from another element, component, region, layer or section. Thus, a first element, component, region, layer or section described below could be termed a second element, component, region, layer or section, without departing from the spirit and scope of the present disclosure.

As used herein, the singular forms “a,” “an” and “the” are intended to include the plural forms as well, unless the context clearly indicates otherwise.

It will be further understood that the terms “comprises,” “comprising,” “includes,” “including,” “have,” and “having,” when used in this specification, specify the presence of the stated features, integers, steps, operations, elements, and/or components, but do not preclude the presence or addition of one or more other features, integers, steps, operations, elements, components, and/or groups thereof. Additionally, the terms “comprise(s)/comprising,” “include(s)/including,” “have/has/having” or similar terms include or support the terms “consisting of” and “consisting essentially of,” indicating the presence of stated features, integers, steps, operations, elements, and/or components, without or essentially without the presence of other features, integers, steps, operations, elements, components, and/or groups thereof.

Spatially relative terms, such as “on,” “below,” “lower,” “under,” “above,” “upper,” and the like, may be used herein for ease of explanation to describe one element or feature's relationship to another element(s) or feature(s) as illustrated in the figures. It will be understood that the spatially relative terms are intended to encompass different orientations of the device in use or in operation, in addition to the orientation depicted in the drawings. For example, if the device in the figures is turned over, elements described as “below” or “beneath” or “under” other elements or features would then be oriented “above” the other elements or features. Thus, the example terms “below” and “under” can encompass both an orientation of above and below. The device may be otherwise oriented (e.g., rotated 90 degrees or at other orientations) and the spatially relative descriptors used herein should be interpreted accordingly.

It will be understood that when an element, such as an area, layer, film, region or portion, is referred to as being “on,” or “connected to” another element, it can be directly on or connected to the other element, or one or more intervening elements may be present. In contrast, when an element or layer is referred to as being “directly on,” “directly connected to”, or “immediately adjacent to” another element or layer, there are no intervening elements or layers present. In addition, it will also be understood that when an element is referred to as being “between” two elements, it can be the only element between the two elements, or one or more intervening elements may also be present.

As used herein, the term “and/or” includes any and all combinations of one or more of the associated listed items.

As used herein, the terms “use,” “using,” and “used” may be considered synonymous with the terms “utilize,” “utilizing,” and “utilized,” respectively.

Sizes of elements in the drawings may be exaggerated for convenience of explanation. In other words, since the sizes and thicknesses of components in the drawings may be arbitrarily illustrated for convenience of explanation, the following embodiments are not limited thereto.

Hereinafter, embodiments of the present disclosure will be described in detail with reference to the accompanying drawings. Unless otherwise noted, like reference numerals denote like elements throughout the attached drawings and the written description, and thus, duplicative descriptions thereof may not be provided.

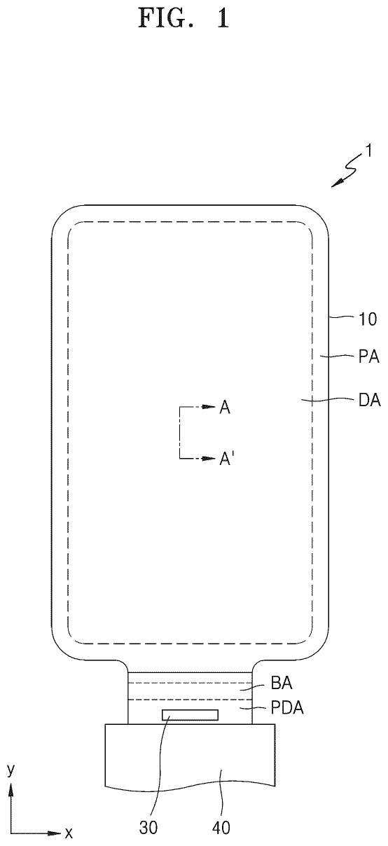

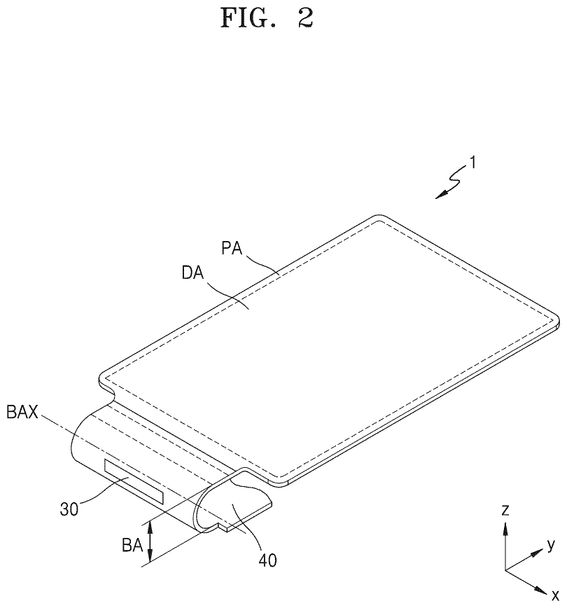

FIG. 1 is a plan view schematically illustrating a display device according to one or more embodiments of the present disclosure, and FIG. 2 is a perspective view schematically illustrating a bent shape of the display device of FIG. 1, according to one or more embodiments of the present disclosure.

In the present specification, the term ‘first direction x’ may be a width direction of a display device 1 or a direction parallel to a bending axis BAX which will be described in more detail later. In addition, the term ‘second direction y’ may be a longitudinal direction of a display device 1, and the term ‘third direction z’ may be interpreted as a stacking direction of components of a display device 1 to be described in more detail later or a direction normal (e.g., perpendicular) to both (e.g., simultaneously) the first direction x and the second direction y. The first direction x, the second direction y, and the third direction z may be directions normal (e.g., perpendicular) to one another.

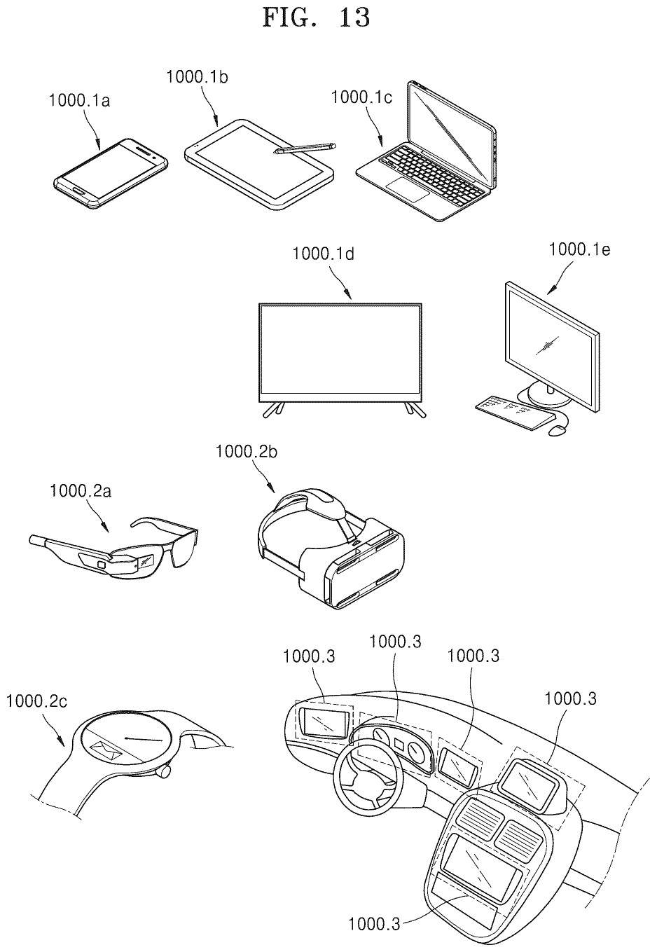

Referring to FIGS. 1 and 2, the display device 1 may be a device configured to display moving images and/or still images, and may be able to provide a screen of a display panel 10 and/or perform input and output of data. Such a display device 1 may be used as a display screen for one or more suitable electronic devices 1000 (see, e.g., FIG. 13) including not only a portable electronic device, such as a mobile phone, a smart phone, a tablet personal computer (PC), a mobile communication terminal, an electronic notebook, an electronic book, a portable multimedia player (PMP), a navigation, or an ultra-mobile PC (UMPC), but also a television, a laptop, a monitor, a sign board, or an Internet of things (IOT).

In one or more embodiments, the display device 1 according to one or more embodiments may be used in an electronic device 1000, including a wearable device, such as a smart watch, a watch phone, a glass-type (kind) display, and a head mounted display (HMD).

In one or more embodiments, the display device 1 according to one or more embodiments may be used as a display for one or more suitable electronic devices 1000, for example, a gauge panel of an automobile, a center information display (CID) placed on a center fascia or dashboard of an automobile, a room mirror display replacing a side mirror of an automobile, and/or as a display placed on the back of the front seat for entertaining purposes for rear seat occupants of an automobile.

The display device 1 according to one or more embodiments of the present disclosure may include a display area DA in which a plurality of pixels are positioned, and a peripheral area PA which is positioned outside the display area DA. In one or more embodiments, the peripheral area PA may include a pad area PDA that is positioned on one side of the display area DA and is an area to which one or more suitable electronic diodes, such as an integrated circuit 30, or a flexible circuit board 40 is electrically attached, and a bending area BA that is positioned between the display area DA and the pad area PDA. As such, the display area DA, the peripheral area PA, the pad area PDA, and the bending area BA may be sectioned (e.g., may be a section) on the substrate.

In one or more embodiments, FIG. 1 is a plan view illustrating a shape of a substrate and/or the like during a manufacturing process of the display device 1. The substrate and/or the like may be, as illustrated in FIG. 2, bent in the bending area BA around a bending axis BAX extending in the first direction x. In this regard, the bending direction may be set such that the pad area PDA may be positioned behind the display area DA. Accordingly, the size of the peripheral area PA recognized by a user may be minimized or reduced.

A circuit cover may be attached on (onto) the integrated circuit 30 and the flexible circuit board 40 of the pad area PDA. The circuit cover may protect the integrated circuit 30 and the flexible circuit board 40 from mechanical shock, and may further add water-proofing and insulation performance to the integrated circuit 30 and the flexible circuit board 40.

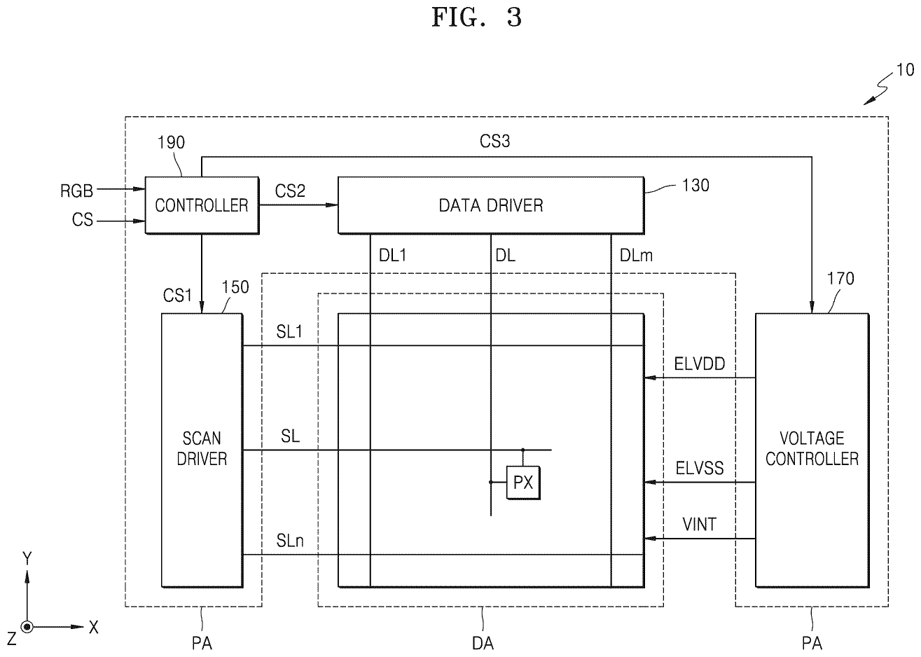

FIG. 3 is a schematic block view illustrating a structure of the display device of FIG. 1, according to one or more embodiments of the present disclosure.

Referring to FIG. 3, the display area DA may include a plurality of scan lines (SL1, . . . , SLn) extending along the first direction x, a plurality of data lines (DL1, . . . , DLm) extending along the second direction y normal (e.g., perpendicular) to the first direction x, and a plurality of sub-pixels PX positioned therein. Herein, m and n may each be a natural number.

Wiring capable of applying electrical signals to the plurality of sub-pixels PX may include the plurality of scan lines (SL1, . . . , SLn), the plurality of data lines (DL1, . . . , DLm), and/or the like. A plurality of scan lines (SL1, . . . , SLn) may be, for example, arranged in multiple rows extending in the first direction x to transmit scan signals to the sub-pixels PX, a plurality of data lines (DL1, . . . , DLm) may be, for example, arranged in multiple columns extending in the second direction y to transmit data signals to the sub-pixels PX, and a plurality of sub-pixels PX may be positioned at intersections of the plurality of scan lines (SL1, . . . , SLn) and the plurality of data lines (DL1, . . . , DLm).

Each sub-pixel PX may include a light-emitting diode so that red light, green light, blue light, or white light may be emitted. For example, each sub-pixel PX may include, although not limited to, an organic light-emitting diode OLED as the light-emitting diode.

The peripheral area PA may include a data driver 130 configured to provide data signals to the display DA, a scan driver 150 configured to provide scan signals to the display DA, a voltage controller 170 configured to control voltages supplied to the display DA, and a controller 190 configured to control the data driver 130, the scan driver 150, and the voltage controller 170 positioned therein.

The voltage controller 170 may generate (e.g., control) a first voltage ELVDD, a second voltage ELVSS, and an initialization voltage VAINT that are supplied to the display DA.

The first voltage ELVDD, the second voltage ELVSS, and the initialization voltage VAINT may be applied to a plurality of sub-pixels PX. For example, the first voltage ELVDD may be a positive voltage, and the second voltage ELVSS may be a negative voltage or a ground voltage. For example, the second voltage ELVSS may have a lower level than the first voltage ELVDD.

The controller 190 may receive image signals RGB and control signals CS from an external source (e.g., a system board). The controller 190 may convert a data format of the image signals RGB to match the interface specifications of the data driver 130, thereby generating image data DATA. The controller 190 may provide image data DATA, of which the data format has been converted, to the data driver 130.

The controller 190 may, in response to the control signal CS provided from the external source, generate and output a first control signal CS1 and a second control signal CS2. The first control signal CS1 may be defined as a scan control signal, and the second control signal CS2 may be defined as a data control signal. The first control signal CS1 may be provided to the scan driver 150. The second control signal CS2 may be provided to the data driver 130.

The scan driver 150 may, in response to the first control signal CS1, generate a plurality of scan signals. The plurality of scan signals may be applied to a plurality of sub-pixels PX via a plurality of scan lines (SL1, . . . , SLn).

The data driver 130 may, in response to the second control signal CS2, generate a plurality of data voltages corresponding to the image data DATA. The plurality of data voltages may be applied to a plurality of sub-pixels PX via data lines (DL1, . . . , DLm). The data driver 130 may concurrently (e.g., simultaneously) provide the data voltages, which are generated in units of sub-pixel rows corresponding to the plurality of sub-pixels PX, to the data lines (DL1, . . . , DLm).

The plurality of sub-pixels PX may, in response to the plurality of scan signals, receive a plurality of data voltages. The plurality of sub-pixels PX may be to emit light with a brightness corresponding to the plurality of data voltages to display an image. The plurality of sub-pixels PX may be to emit light sequentially or concurrently (e.g., simultaneously) to display the image.

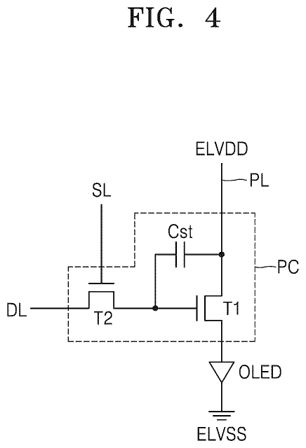

FIG. 4 is a circuit diagram illustrating an equivalent circuit of a single sub-pixel of the display device of FIG. 1, according to one or more embodiments of the present disclosure.

Referring to FIG. 4, a pixel circuit PC may be connected to a display element, for example, an organic light-emitting diode OLED. The pixel circuit PC may be arranged in the display area DA. The pixel circuit PC may include a driving thin-film transistor T1, a switching thin-film transistor T2, and a storage capacitor Cst. In one or more embodiments, the organic light-emitting diode OLED may be to emit red light, green light, or blue light, or may be to emit red light, green light, blue light, or white light.

The switching thin-film transistor T2 may be connected to the scan line SL and the data line DL, and may be to transmit a data signal or data voltage input from the data line DL to the driving thin-film transistor T1, based on a scan signal or switching voltage input from the scan line SL. The storage capacitor Cst may be connected to the switching thin-film transistor T2 and a driving voltage line PL, and may store a voltage corresponding to the difference between the voltage received from the switching thin-film transistor T2 and the first voltage ELVDD supplied to the driving voltage line PL.

The driving thin-film transistor T1 may be connected to the driving voltage line PL and the storage capacitor Cst, and in response to the voltage value stored in the storage capacitor Cst, may control the driving current flowing from the driving voltage line PL to the organic light-emitting diode OLED. The organic light-emitting diode OLED may be to emit light with a certain brightness depending on the driving current. A common electrode of the organic light-emitting diode OLED may receive the second voltage ELVSS.

Although FIG. 4 illustrates one or more embodiments where the pixel circuit PC includes two thin-film transistors and one storage capacitor, the pixel circuit PC may include three, four, five, or more thin-film transistors, and may include two, three, or more capacitors.

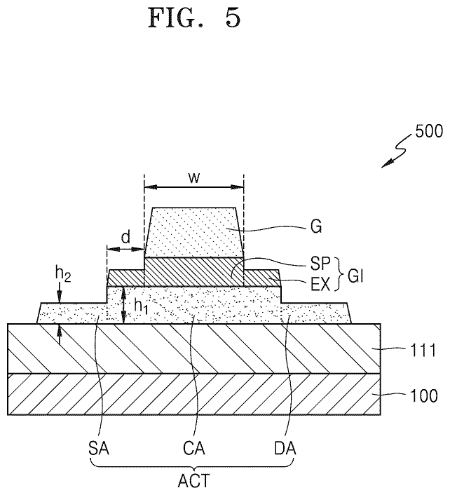

FIG. 5 is a schematic cross-sectional view taken along the line A-A′ of FIG. 1, according to one or more embodiments of the present disclosure.

The display device (e.g., display device 1 of FIG. 1) according to one or more embodiments of the present disclosure may include a substrate 100, a thin-film transistor 500 on the substrate 100, and an organic light-emitting diode OLED (e.g., the organic light-emitting diode OLED of FIG. 4) electrically connected to the thin-film transistor 500.

According to one or more embodiments, the thin-film transistor 500 may be the driving thin-film transistor T1 or the switching thin-film transistor T2 illustrated and described in FIG. 4.

For example, the substrate 100 may be formed of a transparent glass material using SiO₂ as a main component. However, the present disclosure is not limited thereto, and the substrate 100 may also be formed of a transparent plastic material. The plastic material may include polyethersulfone (PES), polyacrylate (PAR), polyetherimide (PEI), polyethylene naphthenate (PEN), polyethyelene terepthalate (PET), polyphenylene sulfide (PPS), polyallylate, polyimide, polycarbonate (PC), cellulose triacetate (TAC), cellulose acetate propionate (CAP), and/or the like. In one or more embodiments, the substrate 100 may have a multi-layer structure including a base layer, which may include any one or more of the aforementioned polymer resins, and a barrier layer. The substrate 100 including the polymer resin may have flexible, rollable, and bendable properties.

A buffer layer 111 may be arranged on the substrate 100. The buffer layer 111 may include an inorganic insulating material, such as silicon nitride, silicon oxynitride, and/or silicon oxide, and may be single-layered or multi-layered including the inorganic insulating material.

A pixel circuit layer may be arranged on the buffer layer 111. A pixel circuit layer may include the thin-film transistor 500 included in the pixel circuit (e.g., the pixel circuit PC of FIG. 4).

The thin-film transistor 500 may include a semiconductor layer Act, and the semiconductor layer Act may include polysilicon. For example, the semiconductor layer Act may include amorphous silicon, an oxide semiconductor, an organic semiconductor, and/or the like. The semiconductor layer Act may include a channel area CA, and a drain area DA and a source area SA arranged at opposite ends of the channel area CA. A gate electrode G may overlap the channel area CA. For example, in a direction normal (e.g., perpendicular) to the third direction (i.e., the direction z of FIG. 2), which is the stacking direction of the components of the display device 1, a width w of the gate electrode G may be smaller than a width of the channel area CA.

The semiconductor layer Act may include the source area SA and the drain area DA that are formed by doping impurities at (on) both ends of the channel area CA. The impurities may vary depending on the type (kind) of the thin-film transistor 500, and may include an N-type (kind) impurity or a P-type (kind) impurity. The channel area CA, the source area SA positioned at one end of the channel area CA, and the drain area DA positioned at the other end of the channel area CA may be referred to as the semiconductor layer Act.

The source area SA or drain area DA formed by doping may be, in some embodiments, interpreted as a source electrode or drain electrode of the thin-film transistor 500. In one or more embodiments, depending on the impurities doped on the semiconductor layer Act, the positions of the source area SA and the drain area DA may be swapped.

The gate electrode G may include a low-resistance metal material. The gate electrode G may include a conductive material including molybdenum (Mo), aluminum (Al), copper (Cu), titanium (Ti), and/or the like, and may be multi-layered or a single layer including the conductive material.

An insulating layer GI may be positioned between the semiconductor layer Act and the gate electrode G and may include an inorganic insulating material such as silicon oxide (SiO₂), silicon nitride (SiₓN_{y}, e.g., where 0<x≤3 and 0<y≤3), silicon oxynitride (SiON), aluminum oxide (Al₂O₃), titanium oxide (TiO₂), tantalum oxide (Ta₂O₅), hafnium oxide (HfO₂), zinc oxide (ZnO_{X}), and/or the like, and/or a (e.g., any suitable) combination thereof. Zinc oxide (ZnO_{X}) may be zinc oxide (ZnO) and/or zinc peroxide (ZnO₂).

For example, the insulating layer GI may include an overlapping portion SP overlapping with the gate electrode G and extension portions EX positioned on opposite and/or outer sides of the overlapping portion SP. For example, the extension portions EX may include one extension portion EX on one end of the overlapping portion SP and another extension portion EX on another (and/or opposite) end of the overlapping portion SP. In the present specification, the term “overlapping portion SP” of the insulating layer GI refers to an area overlapping both (e.g., simultaneously) the gate electrode G and the semiconductor layer ACT. In addition, the term “extension portion EX” of the insulating layer GI refers to an area that does not overlap the gate electrode G, but overlaps the semiconductor layer ACT where a current pass is formed depending on the electric field of the gate electrode G. For example, the channel area CA of the semiconductor layer ACT through which current can flow depending on the electric field of the gate electrode G may overlap with the overlapping portion SP and the extension portions EX of the insulating layer GI. For example, this configuration may enhance the control of the channel region by the gate electrode, thereby improving the switching characteristics and reliability of the display device. Additionally, the presence of the extension portions EX may help reduce leakage current and improve the uniformity of the electric field across the channel.

A width d of each of the extensions EX may be in a range of about 0.5 μm to about 1 μm, and a width w of the overlapping portion SP may be in a range of about 2 μm to about 3 μm. In one or more embodiments, a ratio of the width w of the overlapping portion SP to the width d of each of the extensions EX may be in a range of about 3 to about 4.

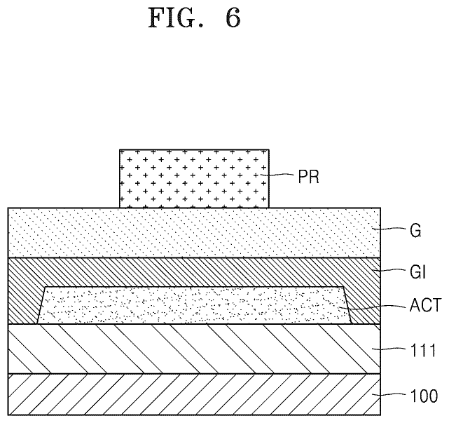

If (e.g., when) the width w of the overlapping portion SP becomes smaller, the width d of the extension portion EX may also become smaller, and if (e.g., when) the width w of the overlapping portion SP becomes larger, the width d of the extension portion EX may also become larger. A method of manufacturing the aforementioned thin-film transistor 500 will be described in more detail later with reference to FIGS. 6 to 10.

When patterning an insulating layer GI under a gate electrode G of a thin-film transistor, the gate electrode G may be used as a mask, and the insulating layer GI may be etched by dry etching once or by wet etching once. When the insulating layer GI is etched by a single dry etching process using the gate electrode G as a mask, the insulating layer GI not covered by the gate electrode G is etched, thereby not forming an extension portion EX in the insulating layer GI. As a result, if the inclined end surface of the insulating layer GI arranged under the gate electrode G (i.e., a side cross-section of the insulating layer GI according to the cross-section parallel to the stacking direction of the thin-film transistor 500) is contaminated (for example, a case where conductive particles and/or the like are deposited on the inclined surface of the insulating layer GI in a subsequent process), there is a concern that the gate electrode G, the contaminated insulating layer GI, and the semiconductor layer ACT under the insulating layer GI may be electrically connected, resulting in a short circuit.

In one or more embodiments, if (e.g., when) the insulating layer GI is etched by a single wet etching process using the gate electrode G as a mask, an under-cut occurs at (on) the lower surface of the gate electrode G due to the isotropy of the wet etching process, thereby forming an extension portion EX in the insulating layer GI. However, because the extension portion EX was formed by the under-cut through the wet etching process, there may be a concern that the width d of the extension portion EX could not be delicately or precisely controlled or selected, and the width d of the extension portion EX could not be made sufficiently short as in embodiments of the present disclosure. When the width d of the extension portion EX is not sufficiently short, there is a concern that, even under the electric field of the gate electrode G, the channel area CA of the semiconductor layer ACT overlapping with the extension portion EX will not be opened, and thus the resistance of the thin-film transistor 500 may increase.

However, as in one or more embodiments of the present disclosure, if (e.g., when) the insulating layer GI of the thin-film transistor 500 manufactured by a process described in more detail later includes an overlapping portion SP overlapping the gate electrode G and extension portions EX positioned on each side (e.g., opposite or outer sides) of the overlapping portion SP, a ratio of the width w of the overlapping portion SP to the width d of each of the extension portions EX is in a range of about 3 to about 4, and the width d of each of the extension portions is in a range of about 0.5 μm to about 1 μm, the distance between the gate electrode G and the semiconductor layer ACT increases even if (e.g., when) the inclined surface of the insulating layer GI is contaminated, so that leakage current caused by short circuit between the gate electrode G and the semiconductor layer ACT may be prevented or reduced, and the semiconductor layer ACT may form a short channel, thereby improving stability and electrical characteristics of the display device 1 and an electronic device including the same. In this disclosure, the term “short channel” refers to a channel in which the channel area CA of the semiconductor layer ACT is opened by fully receiving the electric field of the gate electrode G due to its short width.

In one or more embodiments, a second insulating layer may be provided on the gate electrode G to cover the gate electrode G. The second insulating layer may include, in a similar manner as in the insulating layer GI, an inorganic insulating material, such as silicon oxide (SiO₂), silicon nitride (SiₓN_{y}), silicon oxynitride (SiON), aluminum oxide (Al₂O₃), titanium oxide (TiO₂), tantalum oxide (Ta₂O₅), hafnium oxide (HfO₂), zinc oxide (ZnOₓ), and/or the like, and/or a (e.g., any suitable) combination thereof. Zinc oxide (ZnO_{X}) may be zinc oxide (ZnO) and/or zinc peroxide (ZnO₂).

An upper electrode of a storage capacitor Cst may be arranged on the second insulating layer. The upper electrode may overlap with the gate electrode G under the upper electrode. For example, the gate electrode G and the upper electrode that overlap the second insulating layer placed between the gate electrode G and the upper electrode may form a storage capacitor Cst of a pixel circuit (e.g., the pixel circuit PC in FIG. 4). For example, the gate electrode G may function as a bottom electrode of the storage capacitor Cst. As such, the storage capacitor Cst and the thin-film transistor 500 may overlap each other. However, the present disclosure is not limited thereto, and in one or more embodiments, the storage capacitor Cst may be formed so as not to overlap with the thin-film transistor 500.

The upper electrode may include aluminum (Al), platinum (Pt), palladium (Pd), silver (Ag), magnesium (Mg), gold (Au), nickel (Ni), neodymium (Nd), iridium (Ir), chromium (Cr), calcium (Ca), molybdenum (Mo), titanium (Ti), tungsten (W), and/or copper (Cu), and may be a single layer or multi-layered including the materials as described above.

In one or more embodiments, a light-emitting diode electrically connected to the thin-film transistor 500 may include a pixel electrode, a common electrode, and an intermediate layer between the pixel electrode and the common electrode.

The pixel electrode may include a conductive oxide, such as indium tin oxide (ITO), indium zinc oxide (IZO), zinc oxide (ZnO), indium oxide (In₂O₃), indium gallium oxide (IGO), or aluminum zinc oxide (AZO). In one or more embodiments, the pixel electrode may include a reflective film including silver (Ag), magnesium (Mg), aluminum (Al), platinum (Pt), palladium (Pd), gold (Au), nickel (Ni), neodymium (Nd), iridium (Ir), chromium (Cr), or a compound thereof. In one or more embodiments, the pixel electrode may further include, on/under the reflective film, a film formed of ITO, IZO, ZnO, or In₂O₃.

A pixel-defining film that defines a light-emitting area of the light-emitting diode may be arranged at the edge of the pixel electrode. For example, the pixel-defining film may be formed to cover the edge of the pixel electrode. The pixel-defining film may serve to define pixels by having an opening corresponding to each pixel, i.e., an opening that exposes at least a portion of the light-emitting diode. For example, the opening may be a light-emitting region.

In one or more embodiments, the pixel-defining film may prevent or reduce arcing and/or the like from occurring between the edge of the pixel electrode and the common electrode by increasing the distance between the pixel electrode and the common electrode. The pixel-defining film may include an organic insulating material and/or an inorganic insulating material. For example, the pixel-defining film may include polyimide or hexamethyldisiloxane (HMDSO).

In one or more embodiments, the pixel-defining film may include a light-blocking material, and accordingly may be provided in black. The light-blocking material may include a resin or paste containing carbon black, carbon nanotubes, black dye, metal particles such as nickel, aluminum, molybdenum, and alloys thereof, metal oxide particles (e.g., chromium oxide), or metal nitride particles (e.g., chromium nitride). When the pixel-defining film includes a light-blocking material, external light reflection by metal structures arranged under the pixel-defining film may be reduced.

A spacer may be arranged on the pixel-defining film. The spacer may be used in a method of manufacturing a display device to prevent or reduce damage on the substrate 100. When manufacturing a display panel 10 (as in FIG. 1), a mask sheet may be used. For example, if (e.g., when) the mask sheet enters an opening of the pixel-defining film or is in close contact with the pixel-defining film to deposit a deposition material on the substrate 100, a defect in which a portion of the substrate 100 is damaged or broken by the mask sheet may be prevented or reduced.

The spacer may include an organic insulating material such as polyimide. In one or more embodiments, the spacer may include an inorganic insulating material, such as silicon nitride and/or silicon oxide, or may include an organic insulating material and an inorganic insulating material.

In one or more embodiments, the spacer may include a material different from the pixel-defining film. In one or more embodiments, the spacer may include the same material as the pixel-defining film, and in such embodiments, the pixel-defining film and the spacer may be formed together in a mask process using a halftone mask and/or the like.

An intermediate layer may be formed on the pixel electrode exposed through the opening of the pixel-defining film. The intermediate layer may include a low-molecular weight material or a high-molecular weight material. When a low-molecular weight material is included, a hole injection layer (HIL), a hole transport layer (HTL), an emission layer (EML), an electron transport layer (ETL), an electron injection layer (EIL), and/or the like may have a single structure or a composite stacked structure, and may include one or more suitable organic materials including copper phthalocyanine (CuPc), N,N-di(naphthalene-1-yl)-N,N′-diphenyl-benzidine (NPB), tris-8-hydroxyquinoline aluminum (Alq₃), and/or the like. These layers may be formed by vacuum deposition.

When the intermediate layer includes a polymer material, the intermediate layer may usually have a structure including an HTL and an EML. In one or more embodiments, the HTL may include poly(3,4-ethylenedioxythiophene) (PEDOT), and the EML may include a polymer material such as poly-phenylenevinylene (PPV) and/or polyfluorene. The structure of the intermediate layer is not limited to the description above, and may have one or more suitable structures. For example, the intermediate layer may include a single layer that spans the plurality of pixel electrodes, or may include a layer patterned to correspond to each of the plurality of pixel electrodes.

A common electrode extending above the pixel-defining film may be arranged on the intermediate layer. A common voltage or a second voltage ELVSS may be applied to the common electrode, and the common electrode may be arranged to cover a display area DA (as in display area DA in FIG. 1). For example, the common electrode may be formed integrally (e.g., as a single, continuous layer) to cover a plurality of light-emitting diodes. The common electrode may be a (semi)transparent electrode or a reflective electrode. When the common electrode is a (semi)transparent electrode, the common electrode may have a layer formed of a metal with a small work function, such as Li, Ca, LiF/Ca, LiF/Al, Al, Ag, Mg, and/or compounds thereof, and a (semi)transparent conductive layer including, for example, ITO, IZO, ZnO, and/or In₂O₃. When the common electrode is a reflective electrode, the common electrode may have a layer formed of Li, Ca, LiF/Ca, LiF/Al, Al, Ag, Mg, and/or compounds thereof. Compositions and materials of the common electrode are not limited thereto, and one or more suitable modifications may be possible.

FIGS. 6 to 10 are schematic cross-sectional views of a method of manufacturing the transistor of FIG. 5, according to one or more embodiments of the present disclosure.

Referring to FIGS. 6 to 10 together with FIG. 5, a method of manufacturing a display device (e.g., the display device 1 of FIG. 1) according to one or more embodiments of the present disclosure may include: sequentially stacking a semiconductor layer ACT, an insulating layer GI, a gate electrode G, and a photoresist PR on a substrate 100; after patterning the photoresist PR, performing a first etching on the gate electrode G so that the gate electrode G has a first width l₁; performing a first etching on the insulating layer GI by using the gate electrode G as a mask; performing a second etching on the gate electrode G by using the photoresist PR as a mask so that the gate electrode G has a second width l₂ smaller than the first width l₁; and performing a second etching on the insulating layer GI by using the gate electrode, which has undergone the second etching, as a mask to form an overlapping portion SP overlapping the gate electrode G and extension portions EX positioned on opposite and/or outer sides of the overlapping portion SP and having a thickness smaller than the overlapping portion SP.

For example, referring to FIG. 6, the semiconductor layer ACT, the insulating layer GI, the gate electrode G, and the photoresist PR may be sequentially stacked on the substrate 100. In one or more embodiments, a buffer layer 111 may be arranged between the substrate 100 and the semiconductor layer ACT. For example, before stacking the semiconductor layer ACT on the substrate 100, the buffer layer 111 may be formed on the substrate 100.

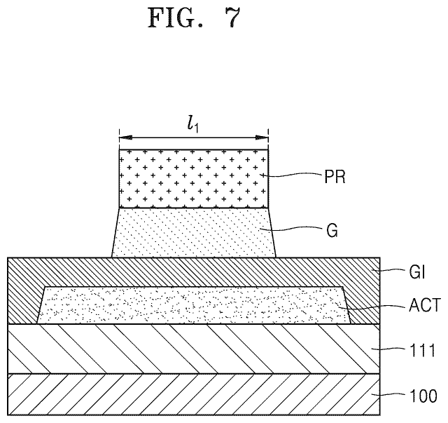

Referring to FIG. 7, after patterning the photoresist PR of the gate electrode G, a first dry etching may be performed on the exposed gate electrode G so that the gate electrode G may have the same first width l₁ as the photoresist PR. However, the first width l₁ of the gate electrode G may not be the same as the first width l₁ of the photoresist PR, for example, as there may be a slight difference in width due to tolerances.

Dry etching may be performed by, for example, using a gas-based plasma. The gate electrode G may be subjected to sputtering with ionized plasma by applying a high-frequency current to reactive gas. As such, sputtering may be promoted by adding additional ions. The gate electrode G may be anisotropically etched, except for the portion where the photoresist PR is deposited, by dry etching. Accordingly, dry etching may enable more delicate and/or precise patterning than wet etching.

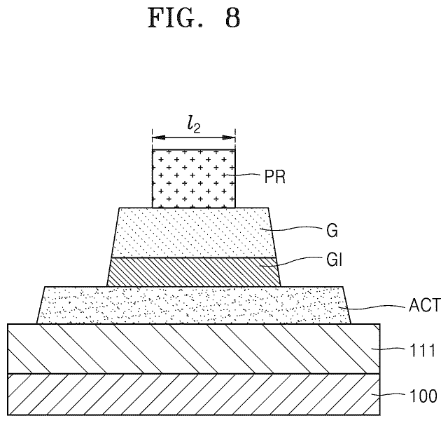

Referring to FIG. 8, the insulating layer GI exposed by the first dry etching on the gate electrode G may be subjected to a first dry etching by using, as a mask, the same photoresist PR and the same gate electrode G.

At (during) the first dry etching on the gate electrode G and the first dry etching on the insulating layer GI, the width of the photoresist PR may be consumed (etched) together with the gate electrode G and the insulating layer GI, and therefore the photoresist may also be reduced. For example, during first dry etching on the gate electrode G and the first dry etching on the insulating layer GI, the width of the photoresist PR may be consumed (etched) together with the gate electrode G and the insulating layer GI and therefore the photoresist may also be reduced from the first width l₁ and the second width l₂. The photoresist PR may be reduced to have a width smaller than the width of the gate electrode G and smaller than the width of the insulating layer GI. For example, this reduction in photoresist width may allow the same photoresist to be used for two separate pattern etchings, helping to reduce manufacturing costs. Additionally, this reduction is important for enhancing etching parameters to maintain critical dimensions and device performance.

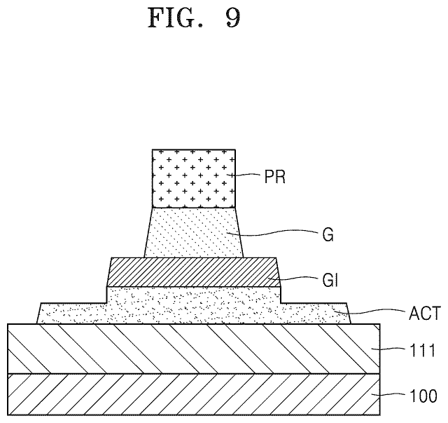

Referring to FIG. 9, by using a photoresist PR having the second width l₂ as a mask, a second dry etching may be performed on the gate electrode G so that the gate electrode G has the second width l₂ smaller than the first width l₁.

In one or more embodiments, by using a photoresist PR as a mask, the source area SA and the drain area DA of the semiconductor layer ACT not covered by the photoresist PR may also be etched together with the gate electrode G and the insulating layer GI. As a result, thicknesses of the source area SA and the drain area DA (i.e., the thickness h₂ of FIG. 5) may be formed thinner than a thickness of the channel area CA (the thickness h₁ of FIG. 5).

For example, the thickness of the channel area CA may be greater than the thicknesses of the source area SA and the drain area DA. For example, a ratio of the thickness of the channel area CA to each of the thicknesses of the source area SA and the drain area DA (e.g., the ratio of the thickness of the channel area CA to the thickness of the source area SA and the ratio of the thickness of the channel area CA to the thickness of the drain area DA) may be in a range of about 1.1 to about 1.3. When the ratio of the thickness of the channel area CA to each of the thicknesses of the source area SA and the drain area DA is within the ranges above, a junction resistance among the source area SA, the drain area DA, and the channel area CA may be reduced, thereby improving current driving performance of the thin-film transistor 500. For example, this thickness differentiation may help form a more efficient electric field distribution across the transistor, improving charge carrier mobility. Additionally, it may contribute to better device reliability and reduced power consumption in high-resolution display applications.

In one or more embodiments, as the source area SA becomes thinner, the electric field is concentrated at the junction between the source area SA and the channel area CA, and thus, if (e.g., when) electrons are injected from the source area SA to the channel area CA, the electron injection efficiency may be improved, thereby preventing or reducing occurrence of parasitic current between the source area SA and the drain are DA. In one or more embodiments, as the source area SA and the drain area DA become thinner, the integration of the display device 1 may be improved.

In one or more embodiments, the second width l₂ of the gate electrode G may be the same as the width l₂ of the photoresist PR, but the present disclosure is not limited thereto. The second width of the gate electrode G may not be the same as the width l₂ of the photoresist PR, for example, as there may be a slight difference in width due to tolerances.

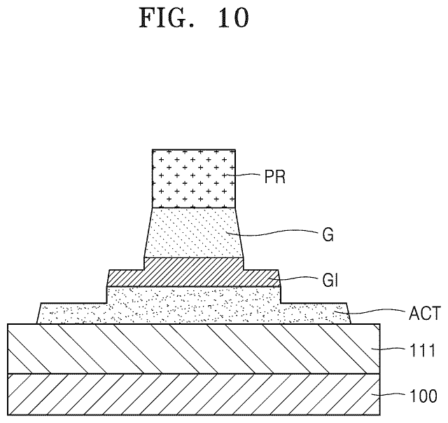

Referring to FIG. 10, the insulating layer GI exposed by the second dry etching on the gate electrode G may be subjected to second dry etching by using the same photoresist PR and the gate electrode G as a mask, so that an overlapping portion SP overlapping the gate electrode G and extension portions EX positioned on opposite and/or outer sides of the overlapping portion SP may be arranged, and so that the extension portions EX may be formed (e.g., may be etched to be) thinner than the overlapping portion SP. In one or more embodiments, a ratio of a thickness of the overlapping portion SP to a thickness of each of the extension portions EX may be in a range of about 1.2 to about 3.

When the ratio of the thickness of the overlapping portion SP to the thickness of each of the extension portions EX is within the ranges above, each of the extension portions EX does not overlap with the gate electrode G. As each of the extension portions EX becomes thinner, a gate voltage may be strongly transmitted to the channel area CA of the semiconductor layer ACT arranged under the extension portions EX of the insulating layer GI to facilitate channel formation, thereby improving the electrical performance of the thin-film transistor 500.

In one or more embodiments, as the overlapping portion SP overlapping with the gate electrode G becomes thicker than the extension portions EX, the parasitic capacitance between the gate electrode G and the channel area CA may be reduced or prevented.

In one or more embodiments, a width of the overlapping portion SP (i.e., the width w in FIG. 5) may be in a range of about 2 μm to about 3 μm, a width of each of the extension portions EX (i.e., the width d in FIG. 5) may be in a range of about 0.5 μm to about 1 μm, and a ratio of the width w of the overlapping portion SP to the width d of each of the extension portions EX may be in a range of about 3 to about 4. For example, the width w of the overlapping portion SP may be the same as the second width l₂ of the gate electrode G, but the width w of the overlapping portion SP and the second width l₁ of the gate electrode G may not be the same, and there may be a slight difference in width due to tolerances.

In one or more embodiments, if (e.g., when) the width w of the overlapping portion SP becomes smaller, the width d of the extension portion EX may also become smaller, and if (e.g., when) the width w of the overlapping portion SP becomes larger, the width d of the extension portion EX may also become larger.

When the width d of each of the extension portions EX is less than 0.5 μm and the inclined end surface of the extension portions EX positioned under the gate electrode G is contaminated, the distance from the gate electrode G to the semiconductor layer ACT under the extension portions EX through the contaminated extension portions EX is short, and thus there may be a risk that the gate electrode G, the contaminated extension portions EX, and the semiconductor layer ACT under the extension portions EX may be electrically connected, resulting in a short circuit. For example, there is a concern that current may flow from the gate electrode G to the semiconductor layer ACT along the contaminated inclined surface of the short extension portions EX.

In one or more embodiments, if (e.g., when) the width d of each of the extension portions EX exceeds 1 μm, there may be a concern that the channel area CA of the semiconductor layer ACT overlapping with the extension portions EX will not be opened even if (e.g., when) the electric field of the gate electrode G increases, thereby increasing the resistance of the thin-film transistor 500. For example, if (e.g., when) the extension portions EX are long, the channel area CA may be difficult to form a short channel.

In one or more embodiments, as described above, the same photoresist PR may be used as a mask during the first dry etching on the gate electrode G, the first dry etching on the insulating layer GI, the second dry etching on the gate electrode G, and the second dry etching on the insulating layer GI. For example, the width of the photoresist PR may be naturally reduced from the first width (i.e., the width l₁ in FIG. 7) to the second width (i.e., the width l₂ in FIG. 8) by the first dry etching on the gate electrode G and the first dry etching on the insulating layer GI.

In one or more embodiments, the photoresist PR and the gate electrode G may be used as a mask during the first dry etching on the insulating layer GI, and may also be used as a mask during the second dry etching on the insulating layer GI.

Accordingly, there is no need to perform a separate patterning process during the first and second dry etching on the gate electrode G and the first and second dry etching on the insulating layer GI, so that process efficiency (e.g., the efficiency of the manufacturing process) of the display device 1 and an electronic device including the same may be improved, and the process cost (manufacturing cost) may also be reduced.

In one or more embodiments, after performing the second etching on the insulating layer GI, stripping may be further performed to remove the photoresist PR remaining on the insulating layer GI, thereby finally forming the thin-film transistor 500 as shown, for example, in FIG. 5.

In one or more embodiments, although FIGS. 5 and 10 depict that the angle formed by the side surface of the overlapping portion SP and the upper surface of the extended portion EX is normal (e.g., perpendicular), it is of course recognized that the angle formed by the side surface of the overlapping portion SP and the upper surface of the extended portion EX may not be normal (e.g., perpendicular), depending on the tolerances.

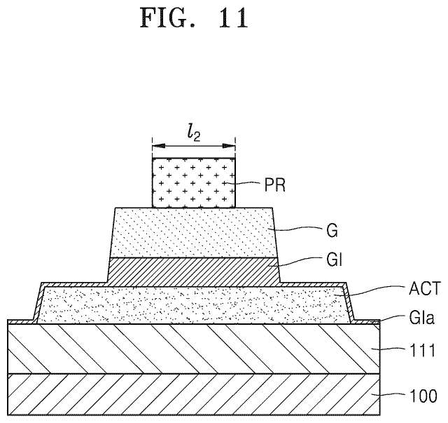

FIG. 11 is a schematic cross-sectional view of a step (e.g., an act or task) of the method of manufacturing the transistor of FIG. 5, according to one or more embodiments of the present disclosure.

FIG. 11 is a diagram illustrating another example of the first dry etching on the insulating layer GI shown and described in FIG. 8, in the method of manufacturing the transistor according to one or more embodiments of the present disclosure.

Referring to FIG. 11, the insulating layer GI exposed by the first dry etching on the gate electrode G may be subjected to first dry etching by using, as a mask, the same photoresist PR and the same gate electrode G.

In some embodiments, the insulating layer GI may be incompletely etched so that the buffer layer 111 and the semiconductor layer ACT are not exposed. For example, a residual film GIa of the insulating layer GI may be formed over the buffer layer 111 and the semiconductor layer ACT.

After performing the first dry etching on the insulating layer GI, the conductive particles of the etched gate electrode G generated during the second dry etching on the gate electrode G may be re-deposited on the buffer layer 111 or the semiconductor layer ACT. As such, if (e.g., when) the conductive particles are re-deposited on the buffer layer 111 or the semiconductor layer ACT, the flatness of the upper surface of the buffer layer 111 or the semiconductor layer ACT may decrease, and accordingly there may be a concern that leakage current may flow through the conductive particles.

However, if (e.g., when) the residual film GIa of the insulating layer GI remains on the buffer layer 111 and the semiconductor layer ACT due to the incomplete etching on the insulating layer GI, the conductive particles of the second-etched gate electrode G may not be re-deposited on the buffer layer 111 or the semiconductor layer ACT, but may be re-deposited on the residual film GIa.

For example, in the presence of the residual film GIa of the insulating layer GI over the buffer layer 111 and the semiconductor layer ACT, the residual film GIa may prevent or reduce the re-deposition of the conductive particles of the gate electrode G on the buffer layer 111 and the semiconductor layer ACT. The conductive particles of the gate electrode (G) re-deposited on the residual film GIa may be removed during the second dry etching on the insulating layer GI.

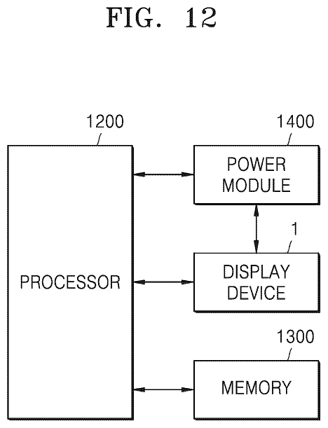

FIG. 12 is a block diagram of an electronic device according to one or more embodiments of the present disclosure.

Referring to FIG. 12, an electronic device 1000 according to one or more embodiments may include a display device 1, a processor 1200, a memory 1300, and a power module 1400.

The display device 1 may receive data from the processor 1200 and provide visual information. The display device 1 may be the aforementioned display device 1 according to one or more embodiments of the present disclosure.

The processor 1200 may include at least one of a central processing unit (CPU), an application processor (AP), a graphic processing unit (GPU), a communication processor (CP), an image signal processor (ISP), and/or a controller. In one or more embodiments, the processor 1200 may operate by executing at least one program.

In the memory 1300, data information necessary for operating the processor 1200 or the display device 1 may be stored. In one or more embodiments, in the memory 1300, at least one program may be stored. When an application stored in the memory 1300 is executed by the processor 1200, an image data signal and/or an input control signal may be transmitted to the display device 1, and the display device 1 may handle the received signal and output image information through a display screen.

The power module 1400 may include a power supply module, such as a power adapter or a battery device, and a power conversion module that converts power supplied by the power supply module to generate power for operating the electronic device 1000. In one or more embodiments, the power module 1400 may supply power to the display device 1.

At least one of the aforementioned components of the electronic device 1000 may be included in the display device 1 according to the aforementioned embodiments. In one or more embodiments, some of individual modules functionally included in a single module may be included in the display device 1, and others may be provided separately from the display device 1.

FIG. 13 is a schematic view of electronic devices according to various embodiments of the present disclosure.

Referring to FIG. 13, one or more suitable electronic devices to which the display device according to one or more embodiments of the present disclosure are applied may include not only an image display electronic device, such as a smart phone 1000.1a, a tablet PC 1000.1b, a laptop 1000.1c, a TV 1000.1d, and a desk monitor 1000.1e, but also a wearable electronic device including the display device, such as smart glasses 1000.2a, a head-mounted display 1000.2b, and a smart watch 1000.2c, and a vehicle electronic device 1000.3 including the display device, such as a center information display (CID) arranged on a gauge board, center fascia, or dashboard of an automobile, and/or a room mirror display.

According to one or more embodiments of the present disclosure, an insulating layer may include an overlapping portion and extension portions, and a width of the overlapping portion to a width of each of the extension portions may have a certain ratio, so that leakage current caused by contamination of the inclined surface of the insulating layer may be prevented or reduced and a short channel may be formed on a semiconductor layer, thereby improving stability and electrical properties of a display device and an electronic device including the same.

However, the effects obtainable through embodiments of the present disclosure are not limited to those described above, and other technical effects not mentioned will be apparent to those skilled in the art from the description of the disclosure set forth herein.

While each of the one or more embodiments described above are embodiments that can be implemented independently, it is also recognized that the structures of each embodiment can be applied in combination with other embodiments.

Unless otherwise defined, all terms (including technical and scientific terms) used herein have the same meaning as commonly understood by one of ordinary skill in the art to which the present disclosure belongs. It will be further understood that terms, such as those defined in commonly used dictionaries, should be interpreted as having a meaning that is consistent with their meaning in the context of the relevant art and/or the present specification, and should not be interpreted in an idealized or overly formal sense, unless expressly so defined herein.

Further, the use of “may” when describing embodiments of the present disclosure refers to “one or more embodiments of the present disclosure.”

As used herein, the term “substantially,” “about,” and similar terms are used as terms of approximation and not as terms of degree, and are intended to account for the inherent deviations in measured or calculated values that would be recognized by those of ordinary skill in the art. “Substantially” as used herein, is inclusive of the stated value and means within an acceptable range of deviation for the particular value as determined by one of ordinary skill in the art, considering the measurement in question and the error associated with measurement of the particular quantity (i.e., the limitations of the measurement system). For example, “substantially” may mean within one or more standard deviations, or within ±30%, 20%, 10%, 5% of the stated value. Also, it should be understood that, even if the terms “about,” “approximately,” or “substantially” are not expressly recited in a given claim element, the scope of such claim element is intended to include variations that are insubstantial or within the understanding of one of ordinary skill in the art. For example, numerical values and ranges provided herein are intended to include tolerances and measurement uncertainties that would be recognized by those skilled in the art, and the claims should be construed accordingly to encompass such equivalents.

Also, any numerical range disclosed and/or recited herein is intended to include all sub-ranges of the same numerical precision subsumed within the recited range. For example, a range of “1.0 to 10.0” is intended to include all subranges between (and including) the recited minimum value of 1.0 and the recited maximum value of 10.0, that is, having a minimum value equal to or greater than 1.0 and a maximum value equal to or less than 10.0, such as, for example, 2.4 to 7.6. Any maximum numerical limitation recited herein is intended to include all lower numerical limitations subsumed therein and any minimum numerical limitation recited in this specification is intended to include all higher numerical limitations subsumed therein. Accordingly, Applicant reserves the right to amend this specification, including the claims, to expressly recite any sub-range subsumed within the ranges expressly recited herein.

The display device, electronic device, device for manufacturing the display device, or any other relevant devices or components according to embodiments of the present disclosure described herein may be implemented utilizing any suitable hardware, firmware (e.g., an application-specific integrated circuit), software, or a combination of software, firmware, and hardware. For example, the various components of the device may be formed on one integrated circuit (IC) chip or on separate IC chips. Further, the various components of the device may be implemented on a flexible printed circuit film, a tape carrier package (TCP), a printed circuit board (PCB), or formed on one substrate. Further, the various components of the device may be a process or thread, running on one or more processors, in one or more computing devices, executing computer program instructions and interacting with other system components for performing the various functionalities described herein. The computer program instructions are stored in a memory which may be implemented in a computing device using a standard memory device, such as, for example, a random access memory (RAM). The computer program instructions may also be stored in other non-transitory computer readable media such as, for example, a CD-ROM, flash drive, or the like. Also, a person of skill in the art should recognize that the functionality of various computing devices may be combined or integrated into a single computing device, or the functionality of a particular computing device may be distributed across one or more other computing devices without departing from the scope of the embodiments of the present disclosure.

A person of ordinary skill in the art, in view of the present disclosure in its entirety, would appreciate that each suitable feature of the various embodiments of the present disclosure may be combined or combined with each other, partially or entirely, and may be technically interlocked and operated in various suitable ways, and each embodiment may be implemented independently of each other or in conjunction with each other in any suitable manner unless otherwise stated or implied.

It will be understood that descriptions of features or aspects within each embodiment should typically be considered as available for other similar features or aspects in other embodiments, unless otherwise described. Thus, as would be apparent to one of ordinary skill in the art, features, characteristics, and/or elements described in connection with a particular embodiment may be used singly or in combination with features, characteristics, and/or elements described in connection with other embodiments unless otherwise specifically indicated. It is to be understood that the foregoing is an illustration of various example embodiments and is not to be construed as limited to the specific embodiments disclosed herein, and that various modifications to the disclosed embodiments, as well as other example embodiments, are intended to be included within the spirit and scope of the present disclosure as defined in the appended claims, and their equivalents.

What is claimed is:

1. A display device comprising:
a substrate;
a thin-film transistor on the substrate; and
a light-emitting diode electrically connected to the thin-film transistor,
wherein the thin-film transistor comprises:
a semiconductor layer,
a gate electrode, and
an insulating layer between the semiconductor layer and the gate electrode,
wherein the insulating layer comprises an overlapping portion overlapping the gate electrode and extension portions respectively positioned on outer sides of the overlapping portion, and
wherein a thickness of the overlapping portion is greater than that of each of the extension portions.

2. The display device of claim 1, wherein a width of each of the extension portions is in a range of about 0.5 μm to about 1 μm.

3. The display device of claim 1, wherein a ratio of a width of the overlapping portion to the width of each of the extension portions is in a range of 3 to 4.

4. The display device of claim 1, further comprising a buffer layer between the substrate and the semiconductor layer.

5. The display device of claim 1, wherein
the semiconductor layer comprises a source area, a drain area, and a channel area between the source area and the drain area, and
the insulating layer is positioned on the channel area.

6. The display device of claim 5, wherein a thickness of the channel area is greater than thicknesses of each of the source area and the drain area.

7. The display device of claim 1, wherein a width of the overlapping portion is in a range of 2 μm to 3 μm.

8. A method comprising:
sequentially stacking a semiconductor layer, an insulating layer, a gate electrode, and a photoresist on a substrate;
after patterning the photoresist, performing a first etching on the gate electrode so that the gate electrode has a first width;
performing a first etching on the insulating layer by utilizing the gate electrode as a mask;
performing a second etching on the gate electrode by utilizing the photoresist as a mask so that the gate electrode has a second width smaller than the first width; and
after performing the second etching on the gate electrode, performing a second etching on the insulating layer by utilizing the gate electrode as a mask to form an overlapping portion overlapping the gate electrode and extension portions respectively positioned on outer sides of the overlapping portion, the extension portions each having a thickness smaller than that of the overlapping portion,
wherein the method is for manufacturing a display device.

9. The method of claim 8, wherein the first etching on the insulating layer and the first etching on the gate electrode are performed by dry etching.

10. The method of claim 8, wherein, during the first etching on the insulating layer, a width of the photoresist is reduced together with the insulating layer.

11. The method of claim 8, wherein the second etching on the insulating layer and the second etching on the gate electrode are performed by dry etching.

12. The method of claim 8, wherein
the semiconductor layer comprises a source area, a drain area, and a channel area between the source area and the drain area, and
during the second etching on the gate electrode, the source area and the drain area are formed thinner than the channel area.

13. The method of claim 12, wherein a ratio of a thickness of the channel area to thicknesses of each of the source area and the drain area is in a range of 1.1 to 1.3.

14. The method of claim 8, wherein, during the first etching on the insulating layer, a residual film of the insulating layer is formed on the semiconductor layer.

15. The method of claim 8, wherein, during the second etching on the insulating layer, a ratio of a thickness of the overlapping portion to a thickness of each of the extension portions is in a range of 1.2 to 3.

16. The method of claim 8, wherein a width of each of the extension portions is in a range of 0.5 μm to 1 μm.

17. The method of claim 8, wherein a ratio of a width of the overlapping portion to a width of each of the extension portions is in a range of 3 to 4.

18. The method of claim 8, further comprising forming a buffer layer on the substrate.

19. The method of claim 8, further comprising after the performing of the second etching on the insulating layer, stripping the photoresist.

20. An electronic device comprising:
a memory in which at least one program is stored;
a processor configured to operate by executing the at least one program;
a display device configured to receive data from the processor to provide visual information; and
a power module configured to supply power to the display device,
wherein the display device comprises:
a substrate;
a thin-film transistor on the substrate; and
a light-emitting diode electrically connected to the thin-film transistor,
wherein the thin-film transistor comprises:
a semiconductor layer,
a gate electrode, and
an insulating layer between the semiconductor layer and the gate electrode,
wherein the insulating layer comprises an overlapping portion overlapping the gate electrode and extension portions respectively positioned on outer sides of the overlapping portion, and
wherein a thickness of the overlapping portion is greater than that of each of the extension portions.
